(19) United States
(12) Patent Application Publication
(10) Pub. No.: US 2025/0359274 A1
(43) Pub. Date: Nov. 20, 2025

(54) SEMICONDUCTOR DEVICES WITH GATE BUS LAYOUTS FOR HANDLING UNCLAMPED INDUCTIVE SWITCHING CURRENT

(71) Applicant: Wolfspeed, Inc., Durham, NC (US)

(72) Inventors: Rahul R. Potera, Apex, NC (US); In-Hwan Ji, Apex, NC (US); Sei-Hyung Ryu, Cary, NC (US)

(21) Appl. No.: 18/663,985

(22) Filed: May 14, 2024

(51) Int. Cl. H01L 29/423

(52) U.S. Cl. CPC H10D 64/518; H10D 64/519

(57) ABSTRACT

A semiconductor device includes semiconductor layer, a gate pad on the semiconductor layer, and a longitudinal gate finger on the semiconductor layer, the longitudinal gate finger having opposing first and second ends. The semiconductor device includes a first gate bus segment on the semiconductor layer. The first gate bus segment extends adjacent the first end of the longitudinal gate finger and has a proximal end nearest the gate pad and a distal end farthest from the gate pad. The first gate bus segment has a first width at the proximal end and a second width at the distal end. The first width is greater than the second width.

### TECHNICAL FIELD

The present disclosure relates to semiconductor devices and, more particularly, to power semiconductor devices having gate resistors.

### BACKGROUND

A wide variety of power semiconductor devices are known in the art including, for example, power Junction Field Effect Transistors (“JFETs”), power Metal Oxide Semiconductor Field Effect Transistors (“MOSFETs”), Insulated Gate Bipolar Transistors (“IGBTs”) and various other devices. These power semiconductor devices are often fabricated from wide bandgap semiconductor materials. Herein, the term “wide bandgap semiconductor” encompasses any semiconductor having a bandgap of at least 1.4 eV. Power semiconductor devices are designed to selectively block or pass large voltages and/or currents. For example, in the blocking state, a power semiconductor device may be designed to sustain hundreds or thousands of volts of electric potential.

Power semiconductor devices having high power ratings are most typically fabricated using silicon carbide, as silicon carbide has a number of advantageous characteristics including, for example, a high electric field breakdown strength, high thermal conductivity, high electron mobility, high melting point and high-saturated electron drift velocity. A conventional silicon carbide-based power semiconductor device typically has a silicon carbide substrate, such as a silicon carbide wafer having a first conductivity type (e.g., an n-type substrate), on which a silicon carbide epitaxial layer structure is formed which may have both first and second conductivity type layers and/or regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

The epitaxial layer structure of most power semiconductor devices includes a drift region and an “active region” that is formed on and/or in the drift region. The active region acts as a main junction for blocking voltage during off-state operation (also referred to as “reverse bias” or “reverse blocking” operation) and current flows through the active region during on-state operation (also referred to as “forward bias” operation). Most power semiconductor devices also have an edge termination region adjacent the active region. The edge termination region is designed to spread the electric fields during reverse blocking operation out over a greater area in order to reduce electric field crowding effects that would otherwise occur along the outer edges of the active region. One or more power semiconductor devices may be formed on the wafer, and each power semiconductor device will typically have its own edge termination region. After the epitaxial layer(s) is/are grown on the wafer and fully processed, the wafer may be diced to separate the individual edge-terminated power semiconductor devices if multiple devices are formed on the same wafer (or other substrate). The power semiconductor devices may have a unit cell structure in which the active region of each power semiconductor device includes a large number of individual cells that are disposed in parallel to each other and that together function as a single power semiconductor device.

A vertical JFET is a three terminal device that has gate, drain and source terminals that are formed on a semiconductor layer structure, which typically comprises a semiconductor substrate with epitaxial layers formed thereon. Source regions that are electrically connected to the source terminal and a drain region that is electrically connected to the drain terminal may be formed in the semiconductor layer structure. A plurality of channel regions are interposed in the semiconductor layer structure between the source regions and the drain region. A gate structure of the vertical JFET may include, for example, a gate bond pad that serves as the gate terminal, a gate pad that is connected to the gate bond pad, a plurality of gate contacts, and one or more gate buses and/or gate contacts that electrically connect the gate pad to the gate contacts. The gate contacts are disposed adjacent the respective channel regions. Power JFETs are typically normally-on devices, meaning that a JFET conducts current when a voltage of 0 volts is applied to the gate structure.

### SUMMARY

A semiconductor device according to some embodiments includes semiconductor layer, a gate pad on the semiconductor layer, and a longitudinal gate finger on the semiconductor layer, the longitudinal gate finger having opposing first and second ends. The semiconductor device includes a first gate bus segment on the semiconductor layer and a gate pad on the semiconductor layer, wherein the first gate bus segment is in electrically conductive contact with the gate pad.

The first gate bus segment extends adjacent the first end of the longitudinal gate finger and has a proximal end nearest the gate pad and a distal end farthest from the gate pad. The first gate bus segment has a first width at the proximal end and a second width at the distal end. The first width is greater than the second width.

The semiconductor device may further include a plurality of longitudinal gate fingers on the semiconductor layer, wherein the plurality of longitudinal gate fingers have different lengths.

The longitudinal gate fingers farther from the gate pad have larger lengths than longitudinal gate fingers closer to the gate pad.

The first gate bus segment supplies a gate current to the gate finger.

The first gate bus segment may increase in width uniformly, nonuniformly, linearly, nonlinearly, monotonically or non-monotonically from the distal end to the proximal end thereof.

The semiconductor device may further include a second gate bus segment that conductively connects the proximal end of the first gate bus segment to the gate pad. The second gate bus segment may have a uniform width.

The second gate bus segment may have a first end in electrically conductive contact with the proximal end of the first gate bus segment and a second end in electrically conductive contact with the gate pad, wherein the second gate bus segment has a first width at the first end and a second width at the second end, wherein the first width is less than the second width.

The second gate bus segment may increase in width from the first end to the second end, linearly, nonlinearly, uniformly, nonuniformly, monotonically or non-monotonically.

The longitudinal gate finger may extend in a first direction, and the second gate bus segment may extend in the first direction. The first gate bus segment may extend in a second direction that is perpendicular to the first direction.

The longitudinal gate finger may be a first longitudinal gate finger, and the semiconductor device may further include a second longitudinal gate finger adjacent to the first longitudinal gate finger and arranged linearly with the first longitudinal gate finger, wherein the first gate bus segment extends between the first longitudinal gate finger and the second longitudinal gate finger.

The semiconductor device may further include a second gate bus segment on the semiconductor layer, wherein the second gate bus segment is in conductive contact with the gate pad and extends along the semiconductor layer adjacent the second end of the longitudinal gate finger, wherein the second gate bus segment has a proximal end nearest the gate pad and a distal end farthest from the gate pad, wherein the second gate bus segment has a third width at the proximal end and a fourth width at the distal end, and wherein the third width is greater than the fourth width.

The second gate bus segment may increase in width from the distal end thereof to the proximal end thereof, linearly, nonlinearly, piecewise-linearly, uniformly, nonuniformly, monotonically or non-monotonically.

The first gate bus segment and the second gate bus segment may be in electrically conductive contact with the gate pad and extend radially outward from the gate pad.

The semiconductor device may further include a silicide region in the semiconductor layer, wherein the gate pad, the first gate bus segment and the longitudinal gate finger are provided within a periphery of the silicide region.

A semiconductor device according to some embodiments includes a semiconductor layer, a first plurality of longitudinal gate fingers on the semiconductor layer and having opposing first and second ends, and first and second gate bus segments on the semiconductor layer. The first gate bus segment extends adjacent first ends of the first plurality of longitudinal gate fingers and the second gate bus segment extends adjacent second ends of the first plurality of longitudinal gate fingers. The first gate bus segment and the second gate bus segment are in electrically conductive contact with the gate pad and extend radially outward from the gate pad.

The semiconductor device may further include a gate pad on the semiconductor layer, wherein the gate bus segment is in electrically conductive contact with the gate pad.

The semiconductor device may further include a plurality of longitudinal gate fingers on the semiconductor layer, wherein the plurality of longitudinal gate fingers have different lengths.

The semiconductor device may further include a gate pad on the semiconductor layer, wherein the gate bus segment is in electrically conductive contact with the gate pad wherein longitudinal gate fingers farther from the gate pad have larger lengths than longitudinal gate fingers closer to the gate pad.

The semiconductor device may further include a second plurality of longitudinal gate fingers that are arranged to extend in a second direction that is different from the first direction, wherein the first gate bus segment extends adjacent a first end of the second plurality of longitudinal gate fingers. The first direction may be perpendicular to the second direction.

The semiconductor device may further include plurality of gate bus segments that extend radially outward from the gate pad adjacent ends of the plurality of longitudinal gate fingers.

The first gate bus segment may have a proximal end nearest the gate pad and a distal end farthest from the gate pad, and the first gate bus segment may have a first width at the proximal end and a second width at the distal end, wherein the first width is greater than the second width.

The semiconductor device may further include a third gate bus segment in electrically conductive contact with the first gate bus segment and the second gate bus segment.

### BRIEF DESCRIPTION OF DRAWINGS

FIG. 1 illustrates a cell of a vertical JFET semiconductor device.

FIGS. 2 and 3 illustrate, in plan view, conventional layouts of vertical JFET semiconductor devices.

FIGS. 4, 5, 6, 7, 8, 9, 10 and 11 illustrate, in plan view, portions of layouts of vertical JFET devices according to various embodiments.

### DETAILED DESCRIPTION

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art.

Although a JFET device is sometimes referred to as a static induction transistor, the term JFET will be used in the description below. However, it will be appreciated that embodiments described herein may be applied to any device that uses a depletion region to modulate the conductivity of a channel in a mesa.

Although some embodiments are described in the context of a silicon carbide JFET device, it will be appreciated that aspects of the inventive concepts may be applicable to other types of devices, such as MOSFETs, insulated gate bipolar transistors (IGBTs) and other types of devices.

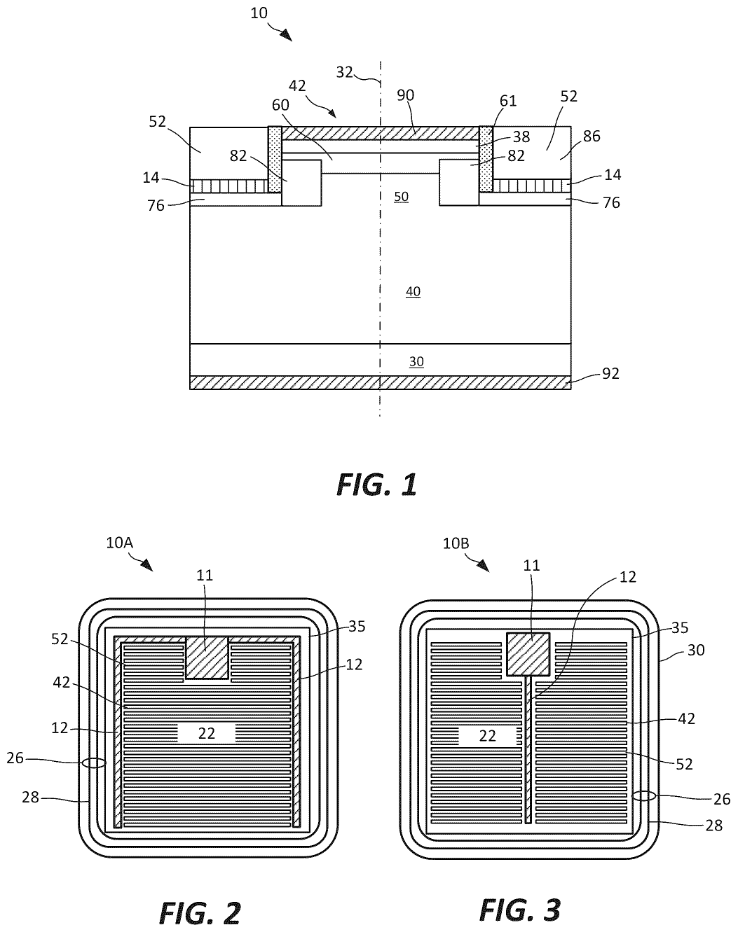

An n-channel vertical JFET structure 10 is shown in FIG. 1. The vertical JFET structure 1 includes an n+ substrate 30 on which an n-drift layer 40 is formed. An n-type channel region 50 is on the drift layer 40, and an n+ source layer 60 is on the channel region 50. An n++ source contact layer 38 is on the n+ source layer 60. A drain ohmic contact 92 is on the substrate 30, and a source ohmic contact 90 is on the source contact layer 38. The channel region 50, source layer 60 and source contact layer 38 are provided as part of a mesa stripe 42 above the drift layer 40. Trenches 52 are formed in the structure 10 adjacent the mesa stripe 42.

A p+ gate region 82 is provided as part of the mesa stripe 42 adjacent the channel region 50. A p++ gate contact region 76 is provided adjacent the gate region 82, and a gate ohmic contact, or gate finger, 14 is formed on the gate contact region 76 in the trenches 52 on opposite sides of the mesa stripe 42. To form the gate finger 14, a layer of metal, such as nickel (Ni), is deposited on the upper surfaces of the gate contact regions 76 and patterned appropriately. The metal is then annealed (for example, by being subjected to high temperature for a period of time) to form metal silicide layers on the upper surfaces of the gate contact regions 76, which provide ohmic contacts to the underlying layers.

An insulation layer 86 is formed in the trenches 52 on the gate finger 14 and the gate contact region 76. The insulation layer 86 may be formed from silicon oxide. Oxide/nitride spacer layers 61 are provided on sidewalls of the mesa stripe 42.

The vertical JFET unit cell structure 10 is symmetrical about the axis 32 and includes two gate regions 82 as part of the mesa stripe 42 on opposite sides of the channel region 50.

The channel of the vertical JFET structure 10 is formed within the mesa stripe 42 between the gate regions 82. The channel width is into the plane of FIG. 1, and the channel length is in the vertical direction from the source region 60 to the drift layer 40. Such a vertical JFET structure with a short channel length may also be called a static-induction transistor (SIT). In a SIT, the channel length is chosen based on a trade-off between low on-resistance in the on-state (short channel) and resistance to drain-induced barrier lowering (DIBL) in the off-state. A p-channel JFET may have a similar structure, but the conductivity types are reversed from those shown in FIG. 1.

In operation, conductivity between the source layer 60 and the substrate 30 is modulated by applying a reverse bias to the gate regions 82 relative to the source layer 60. To switch off an n-channel device such as the JFET structure 10, a negative gate-to-source voltage (or gate voltage) V_{GS} is applied to the gate regions 82. When no voltage is applied to the gate region 82, charge carriers can flow freely from the source layer 60 through the channel region 50 and the drift layer 40 to the substrate 30.

FIGS. 2 and 3 illustrate, in plan view, conventional layouts of vertical JFET semiconductor devices 10A and 10B, respectively. Referring to FIG. 2, a JFET device 10A is formed on a substrate 30. The device 10A includes an active region 22 in which a plurality of alternating mesa stripes 42 and trenches 52 are formed. The active region 22 is surrounded by an edge termination region 26 in which a plurality of guard rings 28 are formed. Guard rings 28 are shown as an example of an edge termination for a power semiconductor device. However, other termination structures, such as field rings, junction termination extension (JTE) regions, etc., can be provided in the edge termination region 26.

A silicide region 35 is formed on an upper surface of the device within the active region 22 in areas other than on the mesa stripes 42. The silicide region 35 forms the gate fingers 14 within the trenches 52. A gate contact pad 11 is formed on the upper surface of the device 10A within the silicide region 35, and a pair of gate buses 12 (also referred to as gate runners 12) extend from the gate contact pad 11 around the outer periphery of the active region 22 adjacent the ends of the mesa stripes 42 and trenches 52 of the device 10A. The gate contact pad 11 and the gate buses 12 may include a conductive material such as a metal silicide and/or a metal layer.

The silicide region 35 provides a low resistance current path between the gate buses 12/gate contact pad 11 and the gate fingers 14 (FIG. 1) that are formed within the trenches 52.

The JFET device 10B shown in FIG. 3 is similar to the JFET device 10A shown in FIG. 2, except that the JFET device 10B includes only a single gate bus 12 which extends from the gate contact pad 11 through the center of the active region 22.

In both JFET devices 10A, 10B, a gate voltage applied to the gate contact pad 11 is conducted through the gate bus 12 and silicide region 35 to the gate ohmic contacts 14 within the trenches 52.

In a switching power device such as a JFET device, a phenomenon referred to as unclamped inductive switching (UIS) may occur when the device is placed under high reverse bias. UIS occurs when current undesirably flows from the drain of the device back through the gate of the device. This subjects the device simultaneously to high current and high voltage, which dissipates a high amount of power in the device and may cause the device to fail when the UIS current exceeds a threshold limit. The ability to handle UIS current is an important quality of a switching power device.

If UIS current is limited by current crowding and filamentation in a part of the semiconductor structure, UIS weakness can be addressed by making the junction breakdown more uniform so that heat is dissipated more uniformly across the device. If UIS current is limited by the current carrying regions outside the semiconductor device, UIS weakness can be addressed by increasing ampacity at those choke points.

When UIS current is not limited in those ways, then gate-drain UIS current causes a voltage drop across the gate resistance, which biases the gate of the device. At sufficient UIS current, this UIS-induced gate bias can exceed the local threshold voltage (VT) of the device and turn on the channel locally (i.e., in the vicinity of the induced gate bias). The channel current induced by UIS biasing will heat up the device locally creating a hotspot in the device. This further reduces VT and increases leakage near the hotspot. This condition creates a positive feedback loop, referred to as a thermal runaway condition, that can cause the device to fail catastrophically at the hotspot.

UIS capability is an important feature of a switching power device and is typically increased by addressing the key limiting factors of UIS rating. If limited by current crowding and filamentation in a part of the semiconductor, UIS weakness can be addressed by making junction breakdown more uniform so that heat is dissipated more uniformly across the device. In case of vertical JFETs when high UIS currents flow through the device to the gate pad, intrinsic gate regions can get biased up to open the JFET channel. Heating from such channel current can cause positive feedback by further reducing threshold voltage and increasing channel current, thereby causing current filamentation and hotspot induced device failure.

Excessive UIS current can damage a semiconductor device. In particular, in a device such as those illustrated in FIGS. 2 and 3, high UIS current that is carried through the gate buses 12 to the gate pad 11 can damage the gate buses 12, which may not be sized to carry such a large amount of current.

In particular, the gate buses 12 of the device 10A include a first portion that extends along the top edge of the device (as viewed in plan view) and a second portion that extends down the side edge of the device (as viewed in plan view) adjacent to ends of the gate fingers 14 in the trenches 42.

The gate buses 12 may be damaged by excessive UIS current in the first portions along the top edge of the device 10B near the gate pad 11, where the most UIS current is carried. As will be appreciated, when UIS occurs, UIS current is carried from the gate fingers 14 in the trenches 42 to the nearest gate bus 12 adjacent to the trench 42. Thus, UIS current in the gate bus 12 increases from a distal end of the gate bus 12 that is farthest from the gate pad 11 towards a proximal end of the gate bus 12 that is closest to the gate pad 11, as the UIS current from each gate finger 12 is added to the current carried by the gate bus 12.

The current carrying capacity of the gate bus 12 could be increased by simply increasing the cross-sectional area of the gate bus 12. However, increasing the size of the gate bus reduces the amount of chip area that can be used for the active region 22 of the device 10. That is, there is a trade-off between increasing the size of the gate bus 12 and decreasing the overall forward current capability of the device 10.

Some embodiments address this problem by providing device layouts including gate bus segments having varying widths. In particular, some embodiments provide semiconductor devices having gate bus segments that increase in width from a distal portion that is farther from the gate pad of the device to a proximal portion that is closer to the gate pad of the device. It will be appreciated that increasing the width of the gate bus segment increases the cross sectional area of the gate bus segment, allowing the current carrying capacity of the gate bus segment to increase correspondingly.

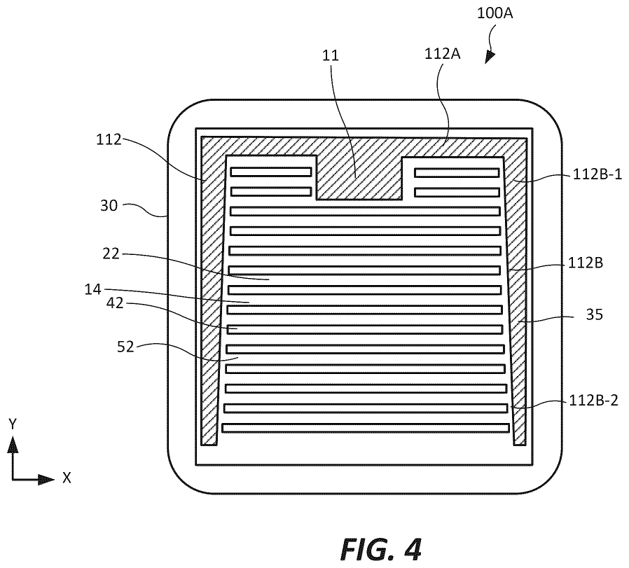

FIGS. 4, 5, 6, 7, 8, 9, 10 and 11 illustrate, in plan view, portions of a layouts of vertical JFET devices according to various embodiments.

Referring to FIG. 4, a device layout of a semiconductor JFET device 100A according to some embodiments is illustrated. The semiconductor JFET device 100A is formed on a substrate 30 and includes an active region 22 in which a plurality of alternating mesa stripes 42 and trenches 52 are formed. The active region 22 is surrounded by an edge termination region in which a plurality of guard rings are formed. For simplicity, the edge termination region is not illustrated in FIG. 4.

A silicide region 35 is formed on an upper surface of the device within the active region 22 in areas other than on the mesa stripes 42. The silicide region 35 forms the gate fingers 14 within the trenches 52. A gate contact pad 11 is formed on the upper surface of the device 100A within the silicide region 35, and a pair of gate buses 112 (also referred to as gate runners 112) extend from the gate contact pad 11 around the outer periphery of the active region 22 adjacent the ends of the mesa stripes 42 and trenches 52 of the device 100A. The gate contact pad 11 and the gate buses 112 may include a conductive material such as a metal silicide and/or a metal layer.

Each of the gate buses 112 includes a first portion 112A that connects to the gate contact pad 11 and that extends laterally from the gate contact pad 11 in a first direction that is parallel to the orientation of the mesa stripes 42 and trenches 52 and a second portion 112B that connects the first portion 112A and that extends along the side of the active region 22 in a second direction that is perpendicular to the orientation of the mesa stripes 42 and trenches 52. That is, the second portion 112B of the gate bus 112 extends adjacent ends of the mesa stripes 42 and trenches 52. The second portion 112B of the gate bus 112 includes a distal end 112B-2 that is farthest from the gate contact pad 11 and a proximal end 112B-1 that is closest to the gate contact pad 11. The width of the second portion 112B of the gate bus 112 increases from the distal end 112B-2 to the proximal end 112B-1 thereof. Because the width of the second portion 112B of the gate bus 112 increases from the distal end 112B-2 to the proximal end 112B-1 thereof, the current carrying capacity of the second portion 112B of the gate bus 112 increases as the second portion 112B of the gate bus 112 passes more and more gate fingers 14. Thus, as UIS current from more gate fingers 14 is conducted to the gate bus 112, the gate bus 112 is able to carry more UIS current without failure.

In some embodiments, the first portion 112A of the gate bus 112 has a width that is substantially the same as the width of the second portion 112B of the gate bus 112 at the proximal end 112B-1 thereof.

In some embodiments, the width of the second portion 112B of the gate bus 112 increases monotonically from the distal end 112B-2 to the proximal end 112B-1 thereof. In some embodiments, the width of the second portion 112B of the gate bus 112 increases linearly from the distal end 112B-2 to the proximal end 112B-1 thereof as illustrated in FIG. 4. In other embodiments, the width of the second portion 112B of the gate bus 112 may increase non-linearly from the distal end 112B-2 to the proximal end 112B-1 thereof. In further embodiments, the width of the second portion 112B of the gate bus 112 may increase piecewise-linearly from the distal end 112B-2 to the proximal end 112B-1 thereof.

Because the widths of the second portions 112B of the gate buses 112 are non-uniform, the lengths of the mesa stripes 42 and trenches 52 in the active region 22 of the device 100A are also non-uniform, and decrease as the widths of the second portions 112B of the gate buses 112 increase.

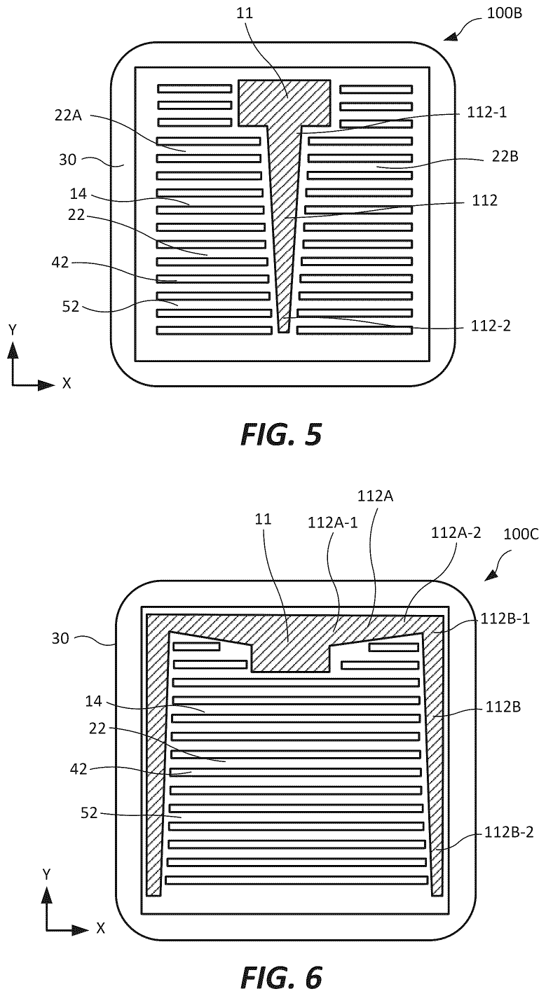

FIG. 5 illustrates a device layout of a semiconductor JFET device 100B according to further embodiments. The layout of the semiconductor JFET device 100B is similar to that of the semiconductor JFET device 100A shown in FIG. 4, except that the semiconductor JFET device 100B includes a single gate bus 112 that extends from the gate contact pad 11 and divides the active region 22 into a first portion 22A and a second portion 22B, each of which includes a plurality of alternating mesa stripes 42 and trenches 52.

The gate bus 112 extends along the inner sides of the active region portions 22A, 22B in a direction that is perpendicular to the orientation of the mesa stripes 42 and trenches 52. That is, the gate bus 112 extends adjacent ends of the mesa stripes 42 and trenches 52. The gate bus 112 includes a distal end 112-2 that is farthest from the gate contact pad 11 and a proximal end 112-1 that is closest to the gate contact pad 11. The width of the gate bus 112 increases from the distal end 112-2 to the proximal end 112-1 thereof. Because the width of the gate bus 112 increases from the distal end 112-2 to the proximal end 112-1 thereof, the current carrying capacity of the gate bus 112 increases as the gate bus 112 passes more and more gate fingers 14. Thus, as UIS current from more gate fingers 14 is conducted to the gate bus 112, the gate bus 112 is able to carry more UIS current without failure.

In some embodiments, the width of the gate bus 112 increases monotonically from the distal end 112-2 to the proximal end 112-1 thereof. In some embodiments, the width of the gate bus 112 increases linearly from the distal end 112-2 to the proximal end 112-1 thereof as illustrated in FIG. 5. In other embodiments, the width of the gate bus 112 may increase non-linearly from the distal end 112-2 to the proximal end 112-1 thereof. In further embodiments, the width of the gate bus 112 may increase piecewise-linearly from the distal end 112-2 to the proximal end 112-1 thereof.

Because the width of the gate bus 112 is non-uniform, the lengths of the mesa stripes 42 and trenches 52 in the active region portions 22A, 22B of the device 100B are also non-uniform, and decrease as the width of the gate bus 112 increases.

FIG. 6 illustrates a device layout of a semiconductor JFET device 100C according to further embodiments. The layout of the semiconductor JFET device 100C is similar to that of the semiconductor JFET device 100A shown in FIG. 4, except that in the semiconductor JFET device 100C, the first portion 112A of the gate bus 112 also increases in width from a distal end 112A-2 thereof that is farthest from the gate contact pad 11 to a proximal end 112A-1 thereof that is closest to the gate contact pad 11.

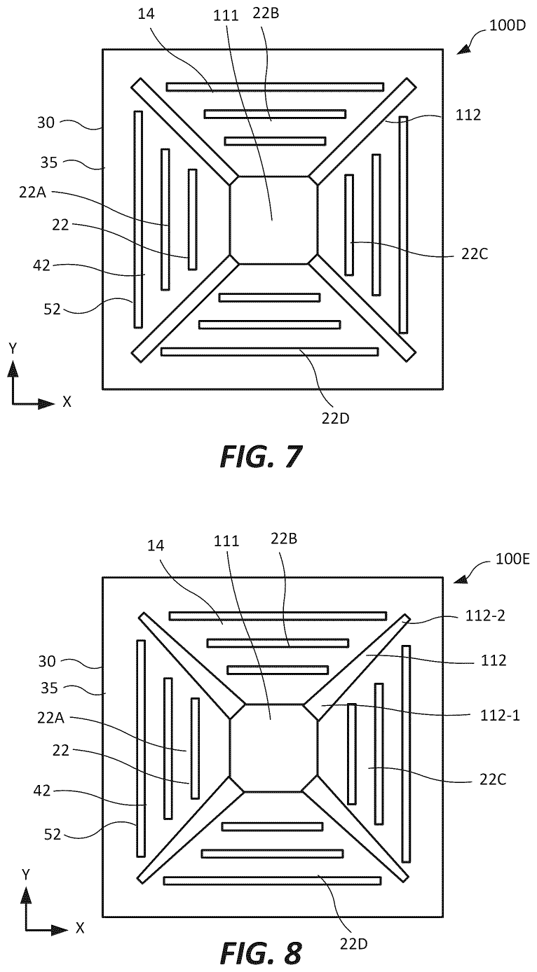

Referring to FIG. 7, a device layout of a semiconductor JFET device 100D according to some embodiments is illustrated. The semiconductor JFET device 100D is formed on a substrate 30 and includes an active region 22 in which a plurality of alternating mesa stripes 42 and trenches 52 are formed. The active region 22 is surrounded by an edge termination region in which a plurality of guard rings are formed. For simplicity, the edge termination region is not illustrated in FIG. 7. The active region is divided into a plurality of regions 22A-22D. Within a region, the mesa stripes 42 and trenches 52 extend in the same direction. However, the mesa stripes 42 and trenches 52 in different active regions 22A-22D extend in different directions. For example, in the embodiment illustrated in FIG. 7, mesa stripes 42 and trenches 52 in the active regions 22A and 22C extend in a first direction (e.g., the Y-direction as shown in FIG. 7), while in the active regions 22B and 22D, the mesa stripes 42 and trenches 52 extend in a second direction (e.g., the X-direction as shown in FIG. 7) that is perpendicular to the first direction.

A silicide region 35 is formed on an upper surface of the device within the active region 22 in areas other than on the mesa stripes 42. The silicide region 35 forms the gate fingers 14 within the trenches 52. A central gate contact pad 111 is formed on the upper surface of the device 100D within the silicide region 35, and a plurality of radial gate buses 112 (also referred to as gate runners 112) extend from the central gate contact pad 111 toward corners of the device 100D between the active regions 22A-22D so that the radial gate buses extend adjacent the ends of the mesa stripes 42 and trenches 52 of the device 100D. The central gate contact pad 111 and the gate buses 112 may include a conductive material such as a metal silicide and/or a metal layer.

By providing more gate buses 112, the UIS current handling capacity of the device may be increased.

FIG. 8 illustrates a device layout of a semiconductor JFET device 100E according to further embodiments. The device layout of the semiconductor JFET device 100E is similar to that of the semiconductor JFET device 100D shown in FIG. 7, except that the radial gate buses 112 have widths that increase from a distal end 112-2 that is farther from the central gate contact pad 111 to a proximal end 112-1 that is closer to the central gate contact pad 111. As with the embodiments described above in connection with FIGS. 4-6, increasing the width of the gate buses 112 closer to the gate contact pad 111 may increase the UIS current capacity of the device while sacrificing less active area of the device.

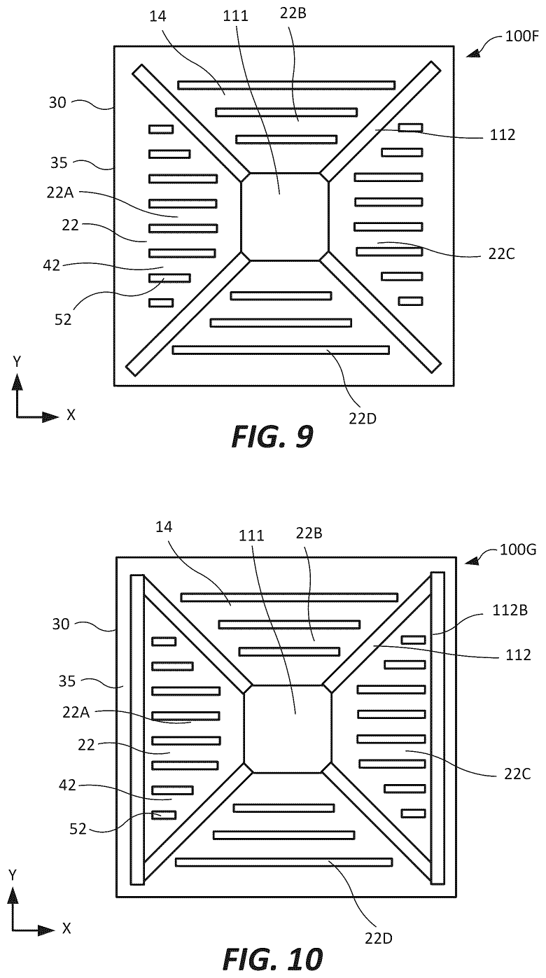

FIG. 9 illustrates a device layout of a semiconductor JFET device 100F according to further embodiments. The device layout of the semiconductor JFET device 100F is similar to that of the semiconductor JFET device 100D shown in FIG. 7, except that the mesa stripes 42 and trenches 52 in all of the active regions 22A-22D extend in the same direction (e.g., the X-direction as shown in FIG. 8).

FIG. 10 illustrates a device layout of a semiconductor JFET device 100G according to further embodiments. The device layout of the semiconductor JFET device 100G is similar to that of the semiconductor JFET device 100F shown in FIG. 9, except that additional gate bus portions 112B are provided adjacent the active regions 22A and 22C to run adjacent to outer ends of the mesa stripes 42 and trenches 52 in those active regions.

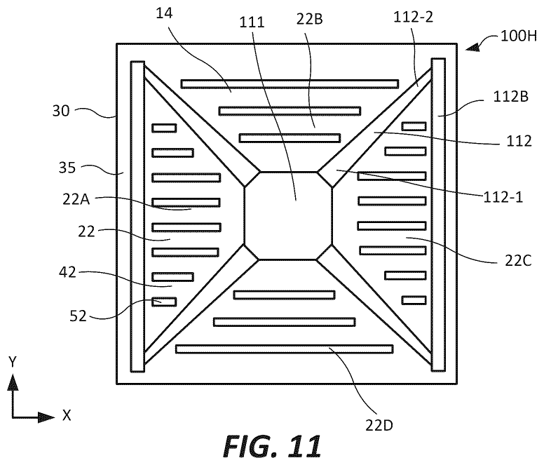

FIG. 11 illustrates a device layout of a semiconductor JFET device 100H according to further embodiments. The device layout of the semiconductor JFET device 100G is similar to that of the semiconductor JFET device 100G shown in FIG. 10, except that the radial gate buses 112 have widths that increase from a distal end 112-2 that is farther from the central gate contact pad 111 to a proximal end 112-1 that is closer to the central gate contact pad 111. As with the embodiments described above in connection with FIGS. 4-6, increasing the width of the gate buses 112 closer to the gate contact pad 111 may increase the UIS current capacity of the device while sacrificing less active area of the device.

The inventive concepts have been described above with reference to the accompanying drawings, in which embodiments are shown. The inventive concepts may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout, except where expressly noted.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The term “in electrically conductive contact” means that two elements are in direct or indirect contact in such a way that electrical current can flow from one element to another. At least part of the connection between the two elements may be electrically resistive.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the inventive concepts are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A semiconductor device comprising:
semiconductor layer;
a gate pad on the semiconductor layer;
a longitudinal gate finger on the semiconductor layer, the longitudinal gate finger having opposing first and second ends; and
a first gate bus segment on the semiconductor layer, wherein the first gate bus segment extends adjacent the first end of the longitudinal gate finger;
wherein the first gate bus segment has a proximal end nearest the gate pad and a distal end farthest from the gate pad;
wherein the first gate bus segment has a first width at the proximal end and a second width at the distal end;
wherein the first width is greater than the second width.

2. The semiconductor device of claim 1, further comprising a gate pad on the semiconductor layer, wherein the first gate bus segment is in electrically conductive contact with the gate pad.

3. The semiconductor device of claim 1, further comprising a plurality of longitudinal gate fingers on the semiconductor layer, wherein the plurality of longitudinal gate fingers have different lengths.

4. The semiconductor device of claim 3, further comprising a gate pad on the semiconductor layer, wherein the first gate bus segment is in electrically conductive contact with the gate pad wherein longitudinal gate fingers farther from the gate pad have larger lengths than longitudinal gate fingers closer to the gate pad.

5. The semiconductor device of claim 1, wherein the first gate bus segment supplies a gate current to the gate finger.

6. The semiconductor device of claim 1, wherein the first gate bus segment increases in width uniformly from the distal end to the proximal end thereof.

7. The semiconductor device of claim 1, wherein the first gate bus segment increases in width nonuniformly from the distal end to the proximal end thereof.

8. The semiconductor device of claim 1, wherein the first gate bus segment increases in width linearly from the distal end to the proximal end thereof.

9. The semiconductor device of claim 1, wherein the first gate bus segment increases in width nonlinearly from the distal end to the proximal end thereof.

10. The semiconductor device of claim 1, wherein the first gate bus segment increases in width monotonically from the distal end to the proximal end thereof.

11. The semiconductor device of claim 1, wherein the first gate bus segment increases in width non-monotonically from the distal end to the proximal end thereof.

12. The semiconductor device of claim 1, further comprising a second gate bus segment that conductively connects the proximal end of the first gate bus segment to the gate pad.

13. The semiconductor device of claim 12, wherein the second gate bus segment has a uniform width.

14. The semiconductor device of claim 12, wherein the second gate bus segment has a first end in electrically conductive contact with the proximal end of the first gate bus segment and a second end in electrically conductive contact with the gate pad, wherein the second gate bus segment has a first width at the first end and a second width at the second end, wherein the first width is less than the second width.

15. The semiconductor device of claim 14, wherein the second gate bus segment increases in width from the first end to the second end, linearly, nonlinearly, uniformly, nonuniformly, monotonically or non-monotonically.

16. The semiconductor device of claim 14, wherein the longitudinal gate finger extends in a first direction, and the second gate bus segment extends in the first direction.

17. The semiconductor device of claim 16, wherein the first gate bus segment extends in a second direction that is perpendicular to the first direction.

18. The semiconductor device of claim 1, wherein the longitudinal gate finger comprises a first longitudinal gate finger, the semiconductor device further comprising a second longitudinal gate finger adjacent to the first longitudinal gate finger and arranged linearly with the first longitudinal gate finger, and wherein the first gate bus segment extends between the first longitudinal gate finger and the second longitudinal gate finger.

19. The semiconductor device of claim 1, further comprising a second gate bus segment on the semiconductor layer, wherein the second gate bus segment is in conductive contact with the gate pad and extends along the semiconductor layer adjacent the second end of the longitudinal gate finger;
wherein the second gate bus segment has a proximal end nearest the gate pad and a distal end farthest from the gate pad;
wherein the second gate bus segment has a third width at the proximal end and a fourth width at the distal end;
wherein the third width is greater than the fourth width.

20. The semiconductor device of claim 19, wherein the second gate bus segment increases in width from the distal end thereof to the proximal end thereof, linearly, nonlinearly, piecewise-linearly, uniformly, nonuniformly, monotonically or non-monotonically.

21. The semiconductor device of claim 20, wherein the first gate bus segment and the second gate bus segment are in electrically conductive contact with the gate pad and extend radially outward from the gate pad.

22. The semiconductor device of claim 1, further comprising a silicide region in the semiconductor layer, wherein the gate pad, the first gate bus segment and the longitudinal gate finger are provided within a periphery of the silicide region.

23. A semiconductor device comprising:
semiconductor layer;
a first plurality of longitudinal gate fingers on the semiconductor layer, the first plurality of longitudinal gate fingers having opposing first and second ends;
a gate pad on the semiconductor layer; and
first and second gate bus segments on the semiconductor layer and in electrically conductive contact with the gate pad;
wherein the first gate bus segment is adjacent the first ends of the first plurality of longitudinal gate fingers and the second gate bus segment is adjacent the second ends of the first plurality of longitudinal gate fingers;
wherein the first gate bus segment and the second gate bus segment extend radially outward from the gate pad.

24. The semiconductor device of claim 23, wherein the gate pad is centrally located on the semiconductor layer.

25. The semiconductor device of claim 23, wherein the first plurality of longitudinal gate fingers have different lengths.

26. The semiconductor device of claim 25, wherein longitudinal gate fingers farther from the gate pad have larger lengths than longitudinal gate fingers closer to the gate pad.

27. The semiconductor device of claim 26, further comprising a second plurality of longitudinal gate fingers, wherein the first plurality of longitudinal gate fingers are arranged to extend in a first direction, and the second plurality of longitudinal gate fingers extend in a second direction that is different from the first direction, wherein the first gate bus segment extends adjacent first ends of the second plurality of longitudinal gate fingers.

28. The semiconductor device of claim 23, wherein the first direction is perpendicular to the second direction.

29. The semiconductor device of claim 23, wherein the first gate bus segment has a proximal end nearest the gate pad and a distal end farthest from the gate pad;
wherein the first gate bus segment has a first width at the proximal end and a second width at the distal end;
wherein the first width is greater than the second width.

30. The semiconductor device of claim 23, further comprising a third gate bus segment in electrically conductive contact with the first gate bus segment and the second gate bus segment.

31. The semiconductor device of claim 30, wherein the third gate bus segment extends parallel to a side of the semiconductor device.
